(19) United States
(12) Patent Application Publication
(10) Pub. No.: US 2013/0285000 A1
(43) Pub. Date: Oct. 31, 2013

(54) SEMICONDUCTOR DEVICE AND MANUFACTURING METHOD OF THE SAME

(71) Applicant: KABUSHIKI KAISHA TOSHIBA, Tokyo (JP)

(72) Inventor: Shinya ARAI, Kanagawa (JP)

(73) Assignee: Kabushiki Kaisha Toshiba, Tokyo (JP)

(21) Appl. No.: 13/786,327

(22) Filed: Mar. 5, 2013

(30) Foreign Application Priority Data
Apr. 27, 2012 (JP) 2012-103061

(51) Int. Cl. H01L 45/00

(52) U.S. Cl. CPC H01L 45/128
USPC 257/3; 438/381

(57) ABSTRACT

According to one embodiment, the semiconductor device includes a substrate, and an interlayer insulating film that is provided with a plug hole, formed on the substrate. Additionally, the device includes a plug layer formed within the plug hole, a heater layer formed on the plug layer within the plug hole, and a phase change film formed on the heater layer within the plug hole. The device additionally includes a wiring layer formed on the phase change film and the interlayer insulating film.

### CROSS-REFERENCE TO RELATED APPLICATION

This application is based upon and claims the benefit of priority from Japanese Patent Application No. 2012-103061, filed Apr. 27, 2012, the entire contents of which are incorporated herein by reference.

### FIELD

Embodiments described herein relate to a semiconductor device and a manufacturing method of the same.

### BACKGROUND

In recent years, the research and development of a Phase Change Random Access Memory (PRAM), a semiconductor memory that uses phase change films, has been vigorously pursued. Generally, a PRAM element contains a heater layer and a phase change layer laminated on the contact plug in that order. Information can be stored in the phase change layer by changing from one phase to another using heat from the heater. However, since the area of phase change film is generally set wider than the area of the contact plug, there is a problem with poor heating efficiency during a reset action (changing the phase after data has been previously stored) of the memory information, causing high power consumption. Additionally, since the lithography to form the contact hole and the lithography to form the phase change film are done separately, the positional gap (layer alignment) of the contact plug and PRAM element is a problem as PRAM memory device features get smaller.

### DESCRIPTION OF THE DRAWINGS

FIG. 1 is a cross-sectional view of the structure of the semiconductor device according to a first embodiment.

FIGS. 2A to 2C are cross-sectional views (1/3) of the manufacturing method of the semiconductor device according to the first embodiment.

FIGS. 3A to 3C are cross-sectional views (2/3) of the manufacturing method of the semiconductor device according to the first embodiment.

FIGS. 4A to 4C are cross-sectional views (3/3) of the manufacturing method of the semiconductor device according to the first embodiment.

FIGS. 5A and 5B are cross-sectional views of the formation method of a heater layer of the semiconductor device according to the first embodiment.

FIG. 6 is a cross-sectional view of the structure of the semiconductor device according to a second embodiment.

FIGS. 7A to 7C are cross-sectional views (1/2) of the manufacturing method of the semiconductor device according to the second embodiment.

FIGS. 8A to 8C are cross-sectional views (2/2) of the manufacturing method of the semiconductor device according to the second embodiment.

### DETAILED DESCRIPTION

A semiconductor device that contains a suitable structure for refinement to smaller device features and a phase change film having excellent heating efficiency are described, as well as a manufacturing method. In general, according to one embodiment, the present invention will be explained below with reference to the provided drawings.

According an embodiment, a semiconductor device includes a semiconductor substrate, and an interlayer insulating film with a plug hole formed on the semiconductor substrate. Additionally, the device includes a plug layer formed within the plug hole, a heater layer formed on the plug layer within the plug hole, and a phase change film formed on the heater layer within the plug hole. The device additionally includes a wiring layer formed on the phase change film and the interlayer insulating film.

### First Embodiment

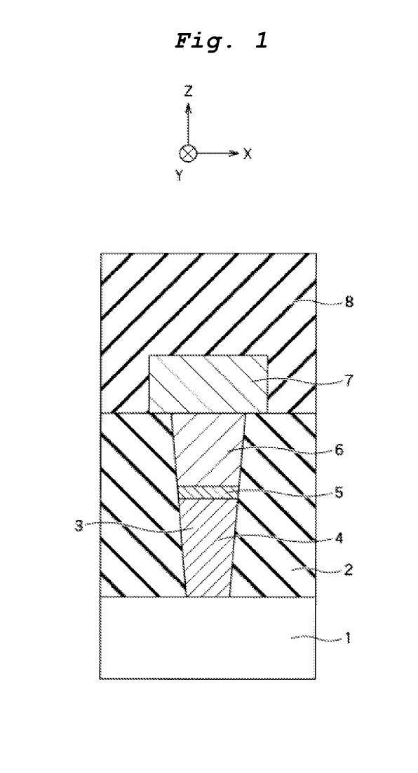

FIG. 1 is the cross-sectional view of the structure of the semiconductor device in the first embodiment. FIG. 1 shows the cross section of the PRAM element that the PRAM is composed of.

The semiconductor device in FIG. 1 includes a semiconductor substrate 1, an interlayer insulating film 2, a contact hole 3, which is an example of a plug hole, a contact plug 4, which is an example of a plug layer, a heater layer 5, a phase change film 6, a wiring layer 7, and an interlayer insulating film 8.

The semiconductor substrate 1 may be, for example, a silicon substrate. In FIG. 1, the X-direction and Y-direction parallel to the main surface of the semiconductor substrate 1, and the Z-direction perpendicular to the main surface of the semiconductor substrate 1 are shown. The X-direction and Y-direction are perpendicular to each other.

The interlayer insulating film 2 is formed on the semiconductor substrate 1 and is provided with the contact hole 3. The interlayer insulating film 2 may be, for example, a silicon oxide film.

The contact plug 4, the heater layer 5, and the phase change film 6 are laminated (stacked) within the contact hole 3 in that respective order.

The contact plug 4 is formed on the semiconductor substrate 1 within the contact hole 3. However, the height of the upper surface of the contact plug 4 is set lower than the height of the upper surface of the interlayer insulating film 2, as a result, within the contact hole 3, in addition to the contact plug 4, the heater layer 5 and the phase change film 6 can be embedded. The contact plug 4 may be, for example, a W (Tungsten) plug, a Cu (Copper) plug, or a polysilicon plug.

The heater layer 5 is the layer that generates heat for heating the phase change layer 6. The heater layer 5 may be, for example, a TiN (Titanium nitride) film or TaN (Tantalum nitride) film.

The phase change film 6 is the film that stores information using the phase change between crystal and amorphous states. The phase change film 6 becomes amorphous when heated to a high temperature (e.g., the melting point) to be melted and then cooled, and becomes crystalline when heated to a lower temperature the high temperature used to form the amorphous state, then slowly cooled. The phase change film 6 may be, for example, chalcogenide films such as GeSbTe (Germanium-Antimony-Tellurium) film.

The materials of the heater layer 5 and the phase change film 6 are selected so that the melting point of the heater layer 5 is higher than the melting point of the phase change film 6. The reason for this is that it is necessary for the heater layer 5 to not melt when changing the phase change film 6 into an amorphous state by supplying heat of the heater layer 5. The melting point of TiN and TaN are approximately 3,000° C., and the melting point of GeSbTe is approximately 620° C.

In addition, since the heater layer 5 in the present embodiment is formed by sputtering, it will be formed on the upper surface of the contact plug 4, but not on the lateral surface of the contact hole 3. That is, the heater layer does not conformably coat the interior surface of the contact hole 3. Therefore, the bottom surface of the phase change film 6 comes in contact with the upper surface of the heater layer 5, and the lateral surface of the phase change film 6 comes in contact with the lateral surface of the contact hole 3.

The wiring layer 7 is formed on the phase change film 6 and the interlayer insulating film 2. The wiring layer 7 may be, for instance, an Al (Aluminum) layer, a Cu (Copper) layer, or a W (Tungsten) layer.

The interlayer insulating layer 8 is formed on the interlayer insulating layer 2 and covers the wiring layer 7. The interlayer insulating layer 8 maybe, for example, a silicon oxide film.

The phase change film 6 is embedded within the contact hole 3. Therefore, in the present embodiment, since the area of the phase change film 6 is almost the same as the area of the contact plug 4, the heating efficiency during the reset action of the memory information of the phase change film 6 may be improved; thus, the power consumption may be reduced. Additionally, since the position of where the phase change film 6 is formed may be decided by self-alignment based on the position of the contact hole 3, even if PRAM development progresses to smaller features, the position gap between the contact plug and PRAM element may easily managed since a single lithographic step may be used in the process.

### (1) Manufacturing Method of the Semiconductor Device in the First Embodiment

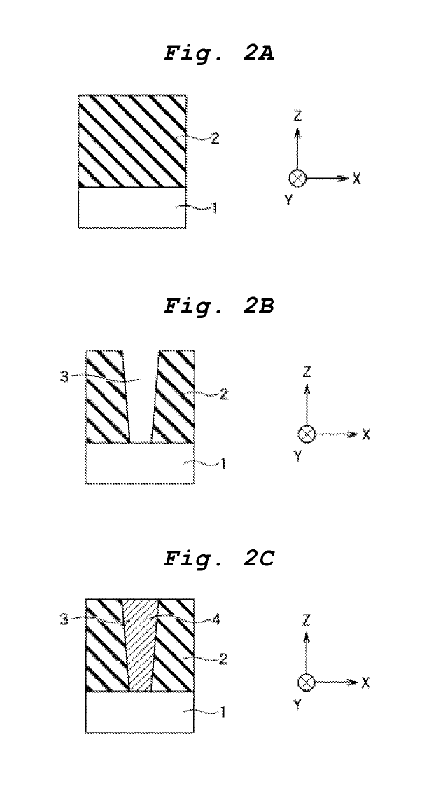

Next, the manufacturing method of the semiconductor device according to the first embodiment will be explained with reference to FIGS. 2A to 4C.

FIG. 2A to FIG. 4C are the cross-sectional view of the manufacturing method of the semiconductor device according to the first embodiment.

First, as shown in FIG. 2A, the interlayer insulating film 2 is formed on the semiconductor substrate 1. Next, as shown in FIG. 2B, the contact hole 3 is formed on the interlayer insulating film 2 by lithography and etching. Next, as shown in FIG. 2C, the contact plug 4 is formed within the contact hole 3.

In FIG. 2C, notice that the height of the upper surface of the contact plug 4 is the same as the height of the upper surface of the interlayer insulating film 2. This contact plug 4 may be formed by, for example, forming the material of the contact plug 4 on all surfaces of the semiconductor substrate 1, and then planarizing the surface of the materials with Chemical Mechanical Polishing (CMP).

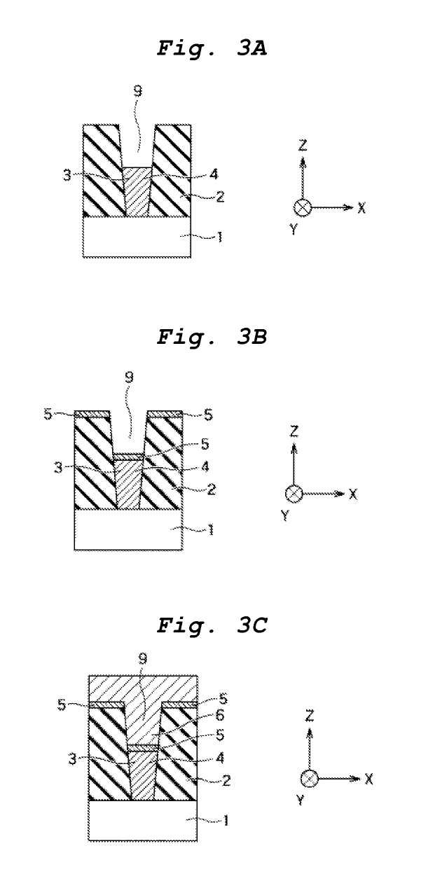

Next, as shown in FIG. 3A, the contact plug 4 is recessed by wet etching or dry etching. As a result, the height of the upper surface of the contact plug 4 becomes lower than the height of the upper surface of the interlayer insulating film 2, and a hole 9 is formed on the contact plug 4.

Next, as shown in FIG. 3B, the heater layer 5 is formed. In the present embodiment, since the heater layer 5 is formed by sputtering, the heater layer 5 is formed only on the upper surface of the interlayer insulating film 2 and the contact plug 4; it is not formed on the lateral surface of the contact hole 3.

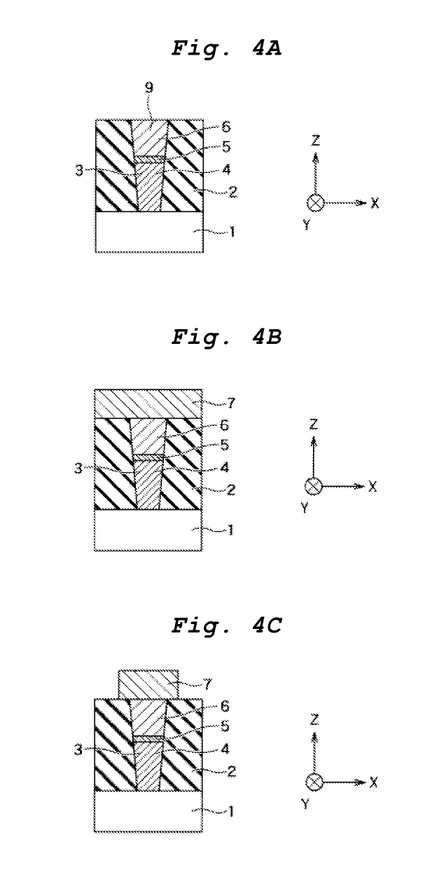

Next, as shown in FIG. 3C, the materials of the phase change film 6 is formed on all surfaces of the semiconductor substrate 1. Next, as shown in FIG. 4A, the surfaces of these materials are polished by CMP. As a result, a structure of the heater layer 5 and the phase change film 6 embedded in that order on the interior of the hole 9 is implemented. In FIG. 4A, notice that the height of the upper surface of the phase change film 6 is the same as the height of the upper surface of the interlayer insulating film 2.

Next, as shown in FIG. 4B, the materials of the wiring layer 7 is formed on all surfaces of the semiconductor substrate 1. Next, as shown in FIG. 4C, these materials are processed by lithography and etching. As a result, the wiring layer 7 is formed on the phase change film 6 and the interlayer insulating film 2.

The wiring layer 7 may also be formed by damascene methods as well. In this case, in the process of FIG. 4B and FIG. 4C, the interlayer insulating film 8 is formed on all surfaces of the semiconductor substrate 1, a wiring groove is formed on the interlayer insulating film 8 by lithography and etching, and then the wiring layer 7 is formed within the wiring groove. Now, the wiring groove is formed in a position where the upper surface of the phase change film 6 is being exposed.

Afterwards, in the present embodiment, various interlayer insulating films, via plugs, wiring layers and such can be formed.

### (2) Formation Method of Heater Layer 5

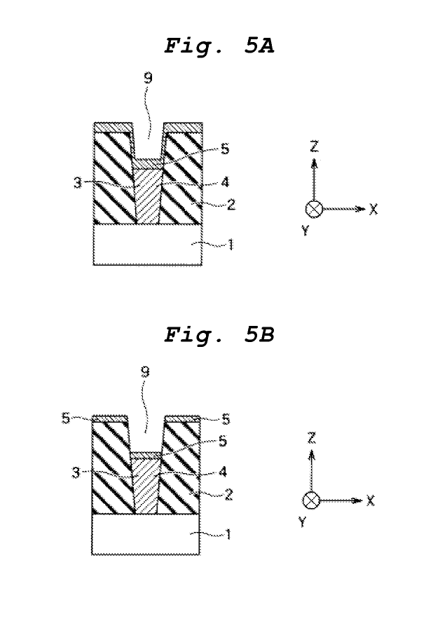

Next, the formation method of the heater layer 5 will be explained in detail with reference to FIGS. 5A and 5B.

FIGS. 5A and 5B are the cross-sectional views of the formation method of the heater layer 5 of the semiconductor device in the first embodiment.

As stated on, in the process in FIG. 3B, since the heater layer 5 is formed by sputtering, the heater layer 5 is only formed on the upper surfaces of the interlayer insulating film 2 and the contact plug 4. However, if the lateral surface of the contact hole 3 is at an angle, a thin heater layer 5 is formed on the lateral surface of the contact hole 3 (refer to FIG. 5A).

It is desired that this thin heater layer 5 is to be removed before the process in FIG. 3C (refer to FIG. 5B). The reason is for this is that, by decreasing the resistance of the heater layer 5, the heat generated by the heater layer 5 is reduced. The thin heater layer 5 may be removed by, for example, thinning the entire heater layer 5 by wet etching. FIG. 5B shows the state where the thin heater layer 5 is removed and the portions of heater layer 5 on the upper surface of insulating film 2 and at the bottom of hole 9 remain.

Now, the heater layer 5 on the lateral surface of the contact hole 3 does not need to be removed in the case when the film thickness is so thin as to not present a significant problem. In this case, the heater layer 5 lies between the upper surface of the contact plug 4 and the bottom surface of the phase change film 6, between the lateral surface of the contact hole 3 and the lateral surface of the phase change film 6.

### (3) Effects of the First Embodiment

Finally, the effects of the first embodiment will be explained.

As stated, in the first embodiment, the phase change film 6 is embedded within the contact hole 3. To be specific, the contact plug 4, the heater layer 5, and the phase change film 6 are laminated within the contact hole 3 in that order.

Therefore, in the first embodiment, since the area of the phase change film 6 is set to be approximately the same as the area of the contact plug 4, the heating efficiency during the reset action of the memory information of the phase change film 6 may be improved; thus, the power consumption may be reduced. Additionally, in the first embodiment, since the position of where the phase change film 6 is formed may be decided by self-alignment based on the position of the contact hole 3, even as device features get progressively smaller, the alignment between the contact plug and PRAM element may be controlled.

The contact hole 3 and the contact plug 4 in the present embodiment may be replaced with a via hole and a via plug. That is, the PRAM element in the present embodiment may be formed within a via hole. In this case, the via plug may include a barrier metal layer and a plug material layer. These barrier metal layer and plug material layer are examples of the plug layers in this disclosure.

The materials for the heater layer 5 may be of materials other than TiN or TaN. Additionally, although the heater layer 5 in the present embodiment is formed with a single material, the heater layer 5 may be formed using two or more types of materials. However, since it is desirable for the heater layer 5 to generate of heat is sufficient quantities, it is preferable that the layer be formed with materials of high electrical resistivity. In addition, materials for the phase change film 6 may be of materials other than GeSbTe as long as the material can switch between phases at temperatures compatible with the memory device.

### Second Embodiment

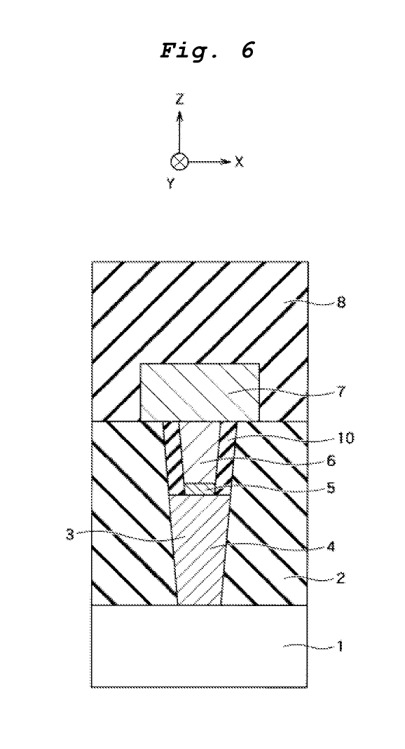

FIG. 6 is the cross-sectional view of the structure of the semiconductor device according to the second embodiment.

The semiconductor device in FIG. 6 includes an insulating film 10, in addition to the components shown in FIG. 1. The insulating film 10 is formed on the lateral surface of the contact hole 3 above the contact plug 4.

As a result, the heater layer 5 and the phase change film 6 are formed within the contact hole 3 in contact with the insulating film 10. Thus, the area of the bottom surface of the heater layer 5 is smaller than the area of the upper surface of the contact plug 4. Additionally, the bottom surface of the phase change film 6 contacts the upper surface of the heater layer 5, and the lateral surface of the phase change film 6 is in contact with the insulating film 10.

According to the second embodiment, the heater layer 5 and the phase change film 6 are formed in smaller sizes. As a result, the total amount of heat required for phase change may be decreased since the phase change film is smaller in size, thus further reducing the power consumption during the reset action.

In addition, according to the second embodiment, miniaturization of the heater layer 5 and the phase change film 6 without reducing the area of the contact plug 4 is possible. Therefore, the heater layer 5 and the phase change film 6 may be formed at sizes smaller than the lower fabrication limit of the contact plug 4 Thus, simply by adjusting the film thickness of the insulating film 10, the dimensions of PRAM element may be adjusted. Therefore, a refined PRAM element that exceeds the lithography limit may be formed.

It is preferable for the thermal conductivity of the insulating film 10 to be as small value as possible. The reason for this is that, if the thermal conductivity of the insulating film 10 is large, then the heat escapes to the insulating film 10, lowering heating efficiency during the reset action.

In the present embodiment, the thermal conductivity of the insulating film 10 is generally less than or equal to the thermal conductivity of the interlayer insulating film 2. This has an effect of making more difficult for heat to escape as compared to the first embodiment. If the interlayer insulating film 2 is a silicon oxide film, as an example of such the insulating film 10, a silicon oxide film and a silicon nitride film may be used. The former will have the same thermal conductivity as the interlayer insulating film 2, and the latter will have a lower thermal conductivity than the interlayer insulating film 2.

The materials of the insulating film 10 may be the same material as the interlayer insulating film 2, or be different material as the interlayer insulating film 2.

### (1) Manufacturing Method of the Semiconductor Device According to the Second Embodiment

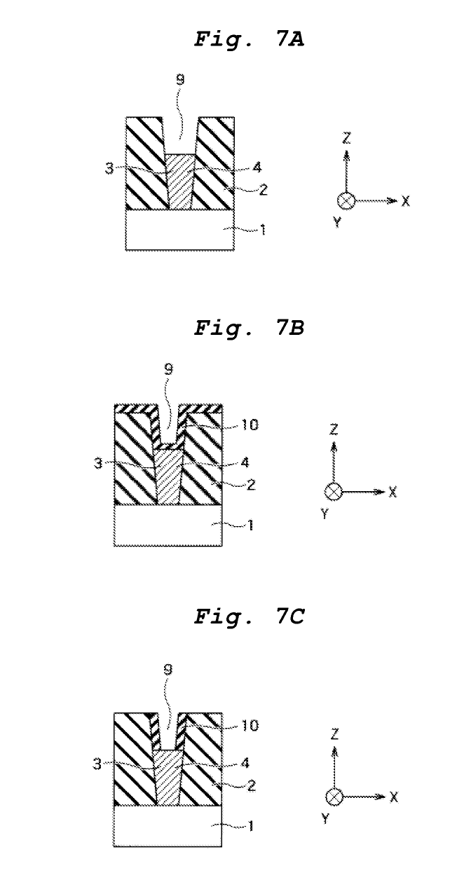

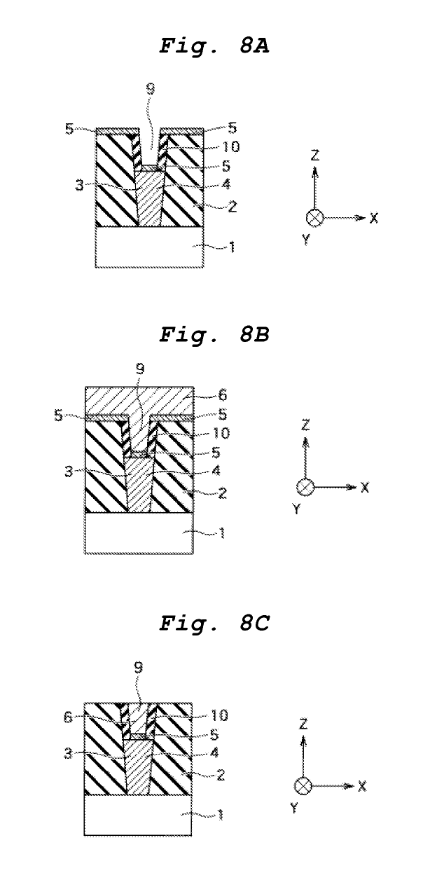

Next, the manufacturing method of the semiconductor device in the second embodiment will be explained with reference to FIGS. 7A to 7C and 8A to 8C. FIGS. 7A to 7C and FIGS. 8A to 8C are the cross-sectional view of the manufacturing method of the semiconductor device in the second embodiment.

First, the processes described in relation to FIG. 2A to FIG. 3A are repeated. As a result, the structure shown in FIG. 7A is obtained.

Next, as shown in FIG. 7B, the insulating film 10 is formed on all surfaces of the semiconductor substrate 1 by Chemical Vapor Deposition (CVD). As a result, the insulating film 10 is formed on the upper surface of the contact plug 4, the lateral surface of the hole 9, and the upper surface of the interlayer insulating film 2.

Next, as shown in FIG. 7C, the insulating film 10 on the upper surface of the contact plug 4 and the upper surface of the interlayer insulating film 2 is removed by anisotropic Reactive Ion Etching (RIE) leaving the insulating film 10 on the lateral surface of the hole 9. As a result, the upper surface of the contact plug 4 at the bottom portion of the hole 9 is exposed.

Next, as shown in FIG. 8A, the heater layer 5 is formed. In the present embodiment, since the heater layer 5 is formed by sputtering, the heater layer 5 is only formed on the upper surfaces of the interlayer insulating film 2 and the contact plug 4, instead of being formed on the surface of the insulating film 10.

Next, as shown in FIG. 8B, materials of the phase change film 6 is formed on all surfaces of the semiconductor substrate 1. Next, as shown in FIG. 8C, the surfaces of these materials are polished by CMP. As a result, a structure of the heater layer 5 and the phase change film 6 embedded in that order on the interior of the hole 9 through the insulating film 10 is realized. In FIG. 8C, notice that the height of the upper surface of the phase change film 6 is the same as the height of the upper surface of the interlayer insulating film 2.

Afterwards, the processes described in relation to FIG. 4B and FIG. 4C are repeated. Additionally, various interlayer insulating films, via plugs, wiring layers and such are formed by standard processes.

Now, when carrying out the process in FIG. 8A, if the lateral surface of the contact hole 3 is at an angle, then the thin heater layer 5 is formed on the surface of the insulating film 10. This thin heater layer 5 may or may not be removed before the process in FIG. 8B. In the former case, the removal method of the heater layer 5 on the surface of the insulating film 10 is done in a similar manner to that in the first embodiment. In the latter case, the insulating film 10 and the heater layer 5 will lie between the lateral surfaces of the contact hole 3 and the phase change film 6.

### (2) Effects of the Second Embodiment

As stated, in the second embodiment, the insulating film 10 is formed on the lateral surface of the contact hole 3 on the contact plug 4, and the heater layer 5 and the phase change film 6 are embedded within the contact hole 3 through the insulating film 10. Therefore, according to the second embodiment, the heater layer 5 and the phase change film 6 may be formed at smaller sizes, and power consumption during the reset action of the memory information of the phase change film 6 may be further reduced.

The material of the insulating film 10 may be the material other than SiO₂ or SiN. Additionally, although the insulating film 10 in the second embodiment is formed with a single material, the layer may be formed using two or more types of materials. Moreover, the film thickness of the insulating film 10 may be set to any film thickness as long as it is a film thickness that does not completely fill (or otherwise close) the contact hole 3.

While the first and the second embodiments have been described, these embodiments have been presented by way of example only, and are not intended to limit the scope of the inventions. Indeed, the novel embodiments described herein may be embodied in a variety of other forms, furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
an interlayer insulating film disposed on the substrate, the interlayer insulating film having a plug hole disposed therein;
a plug layer disposed within the plug hole;
a heater layer disposed on the plug layer within the plug hole;
a phase change film disposed on the heater layer within the plug hole; and
a wiring layer disposed on the phase change film and the interlayer insulating film.

2. The semiconductor device according to claim 1, wherein
a lateral surface of the phase change film is in contact with a lateral surface of the plug hole.

3. The semiconductor device according to claim 1, wherein an area of a bottom surface of the heater layer is smaller than an area of an upper surface of the plug layer.

4. The semiconductor device according to claim 1, further comprising:
an insulating film disposed on a lateral surface of the plug hole above the plug layer,
wherein the heater layer and the phase change film are disposed on the insulating film within the plug hole.

5. The semiconductor device according to claim 4, wherein a thermal conductivity of the insulating film is less than or equal to a thermal conductivity of the interlayer insulating film.

6. The semiconductor device according to claim 4, wherein the heater layer is disposed between an upper surface of the plug layer and a bottom surface of the phase change film, and in between a lateral surface of the insulation film and a lateral surface of the phase change film.

7. The semiconductor device according to claim 4, wherein an area of a bottom surface of the heater layer is smaller than an area of an upper surface of the plug layer.

8. The semiconductor device according to claim 1, wherein the heater layer is disposed between an upper surface of the plug layer and a bottom surface of the phase change film, and between a lateral surface of the plug hole and a lateral surface of the phase change film.

9. The semiconductor device according to claim 4, wherein the insulating film comprises two or more layers.

10. The semiconductor device according to claim 1, wherein an outer edge of an upper surface of the plug layer is substantially aligned with an outer edge of a bottom surface of the heater layer, and an outer edge of an upper surface of the heater layer is substantially aligned with an outer edge of a bottom surface of the phase change film.

11. The semiconductor device of claim 1, wherein the phase change layer is a chalcogenide film.

12. The semiconductor device of claim 1, wherein the plug hole is a via hole, and the plug layer includes a barrier metal layer.

13. A semiconductor device, comprising:
a semiconductor substrate;
an interlayer insulating film disposed on the semiconductor substrate, the interlayer insulating film including a plug hole formed therein
a plug layer disposed within the plug hole;
a heater layer disposed on the plug layer within the plug hole;
a phase change film disposed on the heater layer within the plug hole;
a wiring layer disposed on the phase change film and the interlayer insulating film; and
an insulating film disposed on a lateral surface of the plug hole above the plug layer;
wherein
the heater layer and the phase change film are disposed within the plug hole on the insulating film,
a bottom surface of the phase change film is in contact with an upper surface of the heater layer;
a lateral surface of the phase change film is in contact with the insulating film; and
a thermal conductivity of the insulating film is less than or equal to a thermal conductivity of the interlayer insulating film.

14. The semiconductor device according to claim 13, wherein the insulating film comprises two or more layers.

15. The semiconductor device according to claim 13, wherein the plug layer comprises a barrier metal layer.

16. The semiconductor device according to claim 13, wherein the phase change film is a germanium-antimony-tellurium (GeSbTe) film.

17. A manufacturing method of a semiconductor device, comprising:
forming an interlayer insulating film on a semiconductor substrate;
forming a plug hole in the interlayer insulating film;
forming a plug layer within the plug hole;
forming a heater layer within the plug hole on the plug layer;
forming a phase change film within the plug hole on the heater layer; and
forming a wiring layer on the phase change film and the interlayer insulating film.

18. The manufacturing method of claim 17, further comprising:
forming an insulating layer on a lateral surface of the plug hole above the plug layer.

19. The manufacturing method of claim 17, wherein forming the heater layer within the plug hole on the plug layer includes removing portions of the heater layer deposited on a lateral surface of the plug hole.

20. The manufacturing method of claim 17, wherein forming the wiring layer on the phase change film and the interlayer insulating film involves a damascene process.
